(19) United States
(12) Patent Application Publication
(10) Pub. No.: US 2014/0145196 A1
(43) Pub. Date: May 29, 2014

(54) PIXEL STRUCTURE

(71) Applicant: HannStar Display Corporation, New Taipei City (TW)

(72) Inventors: Ming-Chieh CHANG, Hsinchu County (TW); Chia-Hua YU, New Taipei City (TW); Rong-Fong CHEN, Tainan City (TW)

(21) Appl. No.: 13/911,064

(22) Filed: Jun. 5, 2013

(30) Foreign Application Priority Data
Nov. 26, 2012 (CN) 201210486924.8

(51) Int. Cl. H01L 29/786

(52) U.S. Cl. CPC H01L 29/786
USPC 257/59; 257/72

(57) ABSTRACT

A pixel structure includes a substrate, a gate line, and a transistor. The gate line includes a gate electrode disposed on the substrate, and the gate electrode has at least, one closed opening. The transistor is disposed on the substrate and electrically connected to the gate line. The transistor includes the gate electrode, a dielectric layer, a channel layer, a source electrode, a drain electrode, and a pixel electrode. The dielectric layer is disposed on the gate electrode and the substrate. The channel layer is disposed on a portion of the dielectric layer. At least one portion of the channel layer overlaps at least one portion of the closed opening. The source electrode and the drain electrode are disposed on the channel layer and at opposite sides of the closed opening. The pixel electrode is electrically connected to the drain electrode.

### RELATED APPLICATIONS

This application claims priority to China Application Serial Number 201210486924.8 filed Nov. 26, 2012, which is herein incorporated by reference.

### BACKGROUND

1. Technical Field

The present disclosure relates to a pixel structure.

2. Description of Related Art

A thin-film transistor includes a source electrode, a drain electrode, and a gate electrode. A channel layer disposed between the source electrode and the drain electrode overlaps at least one portion of the gate electrode and isolates to the gate electrode. A portion of the channel layer overlapping the gate electrode becomes conductive when a forward voltage is applied to the gate electrode, such that the source electrode and the drain electrode are electrically connected to each other via the channel layer. In contrast, a nonconductive state is generated in the channel layer between the source electrode and the drain electrode when no voltage is applied to the gate electrode. Therefore, the thin-film transistor can be regarded as a switch element.

The known thin-film transistor can be made of the material such as amorphous silicon, poly-silicon, oxide semiconductor, and metal oxide semiconductor. When such thin-film transistor e is applied as a switch element in a display, the leakage current may be so high that the source electrode and the drain electrode are electrically connected to each other via the channel layer even though the gate electrode is uncharged. Once the thin-film transistor fails to switch precisely, the current of a pixel electrode electrically connected to the thin-film transistor may leakage, so as not to effectively maintain the voltage of the pixel electrode for a certain period of time,

### SUMMARY

The present invention provides a pixel structure to prevent the leakage current of the thin-film transistor. The pixel structure includes a substrate, a gate line, and a transistor. The gate line includes a gate electrode disposed on the substrate, and the gate electrode has at least one closed opening. The transistor is disposed on the substrate and is electrically connected to the gate line. The transistor includes the gate electrode, a dielectric layer, a channel layer, a source electrode, a drain electrode, and a pixel electrode. The dielectric layer is disposed on the gate electrode and the substrate. The channel layer is disposed on a portion of the dielectric layer. At least one portion of the channel layer overlaps at least one portion of the closed opening. The source electrode and the drain electrode are disposed on the channel layer and are respectively disposed at opposite sides of the closed opening. The pixel electrode is electrically connected to the drain electrode.

In one or more embodiments, the gate electrode can be a portion of the gate line.

In one or more embodiments, the gate electrode can be branched from the gate line.

In one or more embodiments, the dosed opening can be a quadrilateral. Two opposite sides of the closed opening are respectively next to the source electrode and the drain electrode, and the other two sides of the dosed opening are not attached to the channel layer.

In one or more embodiments, the gate electrode optionally includes a plurality of the closed opening. The source electrode and the drain electrode are respectively disposed on the opposite sides of the closed openings.

In one or more embodiments, a sum of gaps of two sides of the closed openings parallel to the source electrode and the drain electrode can be 1.5 μm to 5 μm.

In one or more embodiments, a gap of two sides of the closed opening next to the source electrode and the drain electrode can be 1.5 μm to 5 μm.

In one or more embodiments, the transistor optionally further includes a passivation covering the channel layer, the source electrode, and the drain electrode.

In one or more embodiments, the transistor optionally further includes two doping layers respectively disposed between the channel layer and the source electrode, and between the channel layer and the drain electrode.

In one or more embodiments, the structure of the transistor can be a back channel etching (BCE) type, a channel project (CHP) type, a coplanar type, or a stagger type.

### BRIEF DESCRIPTION OF THE DRAWINGS

FIG. 1 is a top view of a pixel structure according to the first embodiment of the present invention;

FIG. 2 is a top view of a transistor in FIG. 1;

FIG. 3 is a cross-section view along line A-A of FIG. 2;

FIG. 4 is a cross-section view along line B-B of FIG. 2;

FIG. 5 is a top view of the transistor according to the second embodiment of the present invention; and

FIG. 6 is a top view of the transistor according to the third embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically depicted in order to simplify the drawings.

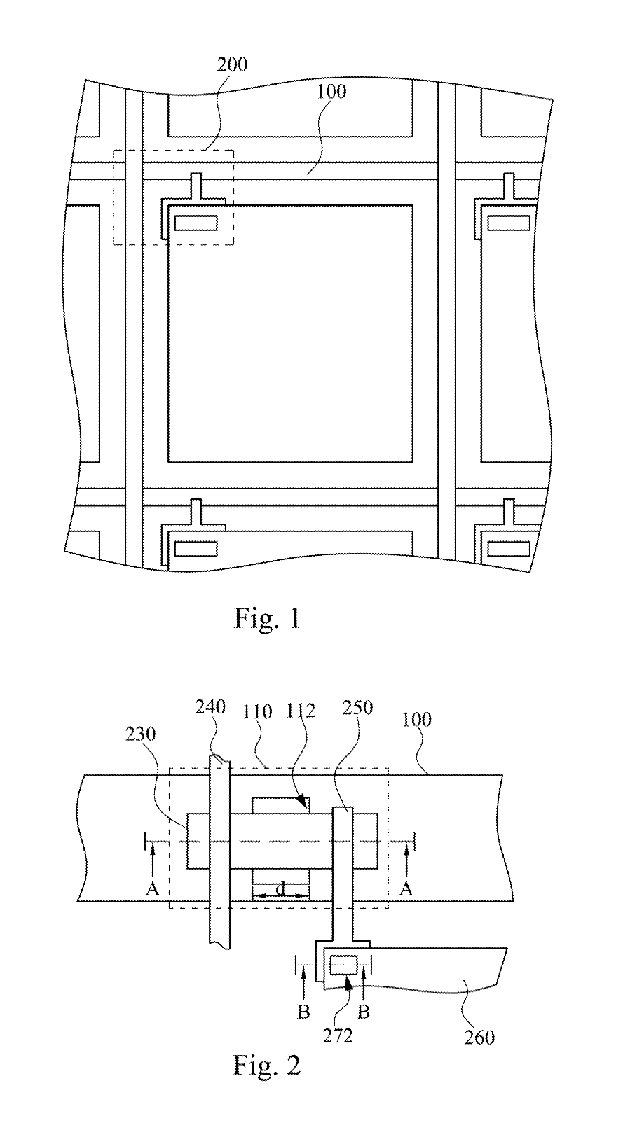

FIG. 1 is a top view of a pixel structure according to the first embodiment of the present invention. The pixel structure includes a substrate 210 (see FIG. 2), a gate line 100, and a transistor 200. The transistor 200 is electrically connected to the gate line 100. It should be noted that the top view of the pixel structure in FIG. 1 is only illustrative, and the scope of the present invention should not be limited to this respect. A person having ordinary skill in the art may design the top view of the pixel structure according to actual requirements.

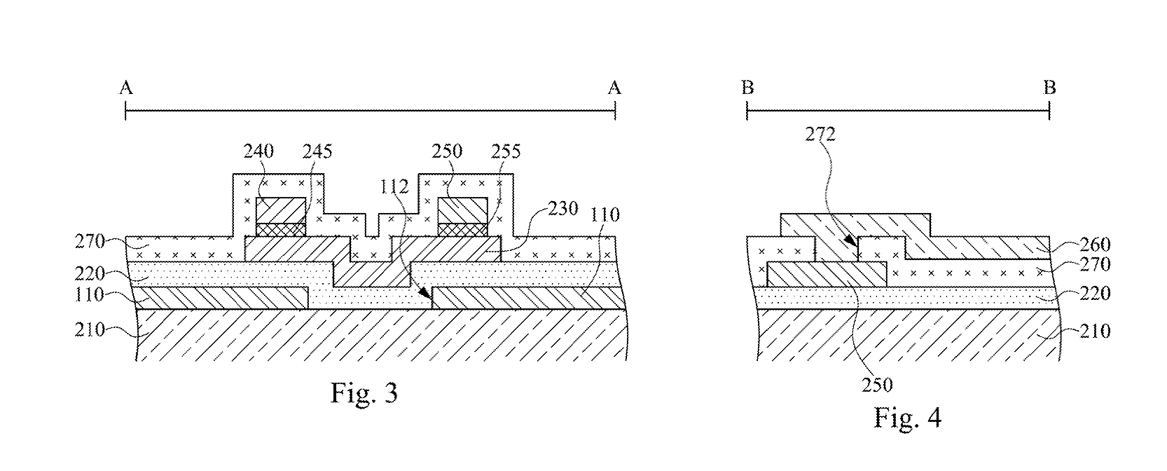

Referring to FIG. 2 to FIG. 4. FIG. 2 is a top view of the transistor 200 in FIG. 1. FIG. 3 is a cross-section view along line A-A of FIG. 2. FIG. 4 is a cross-section view along line B-B of FIG. 2. The transistor 200 is disposed on the substrate 210, and the transistor 200 includes a gate electrode 110, a dielectric layer 220, a channel layer 230, a source electrode 240, a drain electrode 250, and a pixel electrode 260. The gate electrode 110 is disposed on the substrate 210, and the gate electrode 110 has at least one closed opening 112. The dielectric layer 220 is disposed on the gate electrode 110 and the substrate 210. The channel layer 230 is disposed on a portion of the to dielectric layer 220. At least one portion of the channel layer 230 overlaps at least one portion of the closed opening 112, and another portion of the channel layer 230 overlaps the gate electrode 110. The source electrode 240 and the drain electrode 250 are separately disposed on the channel layer 230, and disposed at opposite sides of the closed opening 112. The pixel electrode 260 is electrically connected to the drain electrode 250.

For the transistor 200, the current flowing through the channel layer 230 almost has the same value as the current of a transistor without the closed opening 112 when the gate line 100 provides a forward voltage to the gate electrode 110. In contrast, the current flowing through the channel layer 230 has a value much smaller than the current of a transistor without the closed opening 112 when the gate line 100 provides a reverse voltage to the gate electrode 110. Therefore, the pixel structure according to the present embodiment can restrain the leakage current.

In this embodiment, the gate electrode 110 is a portion of the gate line 100, i.e., there is no substantially edge between the gate electrode 110 and the gate line 110. In other words, the dosed opening 112 is disposed on the gate line 100. The manufacture of the pixel structure with the aforementioned design is more convenient. A manufacturer does not need to design the pattern of the gate electrode 110 when the gate line 100 is patterned. The manufacturer can just form the closed opening 112 at a specific position where is going to form the transistor 200 on the gate line 100, and no more extra process is needed.

The shape of the closed opening 112 can be a quadrilateral, such as a square or a rectangular. However, the scope of the claimed invention should to not be limited in this respect. In one or more embodiments, two sides opposite to each other of the closed opening 112 are respectively next to the source electrode 240 and the drain electrode 250, and the other two sides of the closed opening 112 are not attached to the channel layer 230. Therefore, the current flowing through in the channel layer 230 between the source electrode 240 and the drain electrode 250, especially the leakage current flowing from the drain electrode 250 to the source electrode 240, definitely passes the closed opening 112, such that the leakage current can be restricted.

A gap d between the two sides of the closed opening 112 next to the source electrode 240 and the drain electrode 250 may be between 1.5 μm to 5 μm to restrain or reduce the leakage current. It should be understood that the gap d is illustrative only and should not limit the scope of the claimed invention. A person having ordinary skill in the art may design a proper gap d according to actual requirements.

The transistor 200 may further include a passivation 270 covering the channel layer 230, the source electrode 240, and the drain electrode 250 for protecting the transistor 200. The passivation 270 may include a through hole 272 to expose the drain electrode 250, such that the pixel electrode 260 can be electrically connected to the drain electrode 250 through the through hole 272. The material of the passivation 270 includes silicon nitride, silicon dioxide, silicon nitride oxide, aluminum oxide, or any combination thereof.

The transistor 200 may include two doping layers 245 and 255. The doping layer 245 is disposed between the channel layer 230 and the source electrode 240, and the doping layer 255 is disposed between the channel layer 230 and the drain electrode 250. The material of the doping layers 245 and 255 may be N-type doping amorphous silicon.

In addition, a metal layer can be formed on the substrate 210, and then be patterned to form the gate electrode 110. The material of the metal layer includes MoW, Mo, Al, Ti, Ag, Au, or any combination thereof. The metal layer may be formed by a physical vapor deposition process, such as a sputtering deposition process, or a chemical vapor deposition process. The metal layer may be patterned to form the gate electrode 110 by the photolithography and etching processes. Moreover, since the forming process and the materials of the source electrode 240 and the drain electrode 250 are the same as that of the gate electrode 110, therefore, these are not repeated herein.

The material of the dielectric layer 220 includes silicon nitride, silicon dioxide, silicon nitride oxide, aluminum oxide, or any combination thereof. The material of the channel layer 230 includes amorphous silicon, poly-silicon, amorphous indium gallium zinc oxide (a-IGZO), amorphous indium zinc oxide (a-IZO), gallium nitride, or any combination thereof. The material of the pixel electrode 260 includes indium zinc oxide, indium tin oxide, or any combination thereof. It should be understood that the materials and the forming processes mentioned above are illustrative only and should not limit the scope of the claimed invention. A person having ordinary skill in the art may choose the materials and the forming processes of each layer mentioned above according to actual requirements.

It should be noticed that the structure of the transistor 200 should not be limited in the respect mentioned above, i.e. a back channel etching (BCE) type. In one or more embodiments, the structure of the transistor 200 may be the BCE type, a channel project (CHP) type, a coplanar type, or a stagger type as long as the gate electrode 110 of the transistor 200 includes at least one closed opening 112, and at least one portion of the channel layer 230 is disposed on the closed opening 112.

It should be understood that the details of foregoing pixel structure will not be described in detail in the following, and only the variations in the following embodiments will be described.

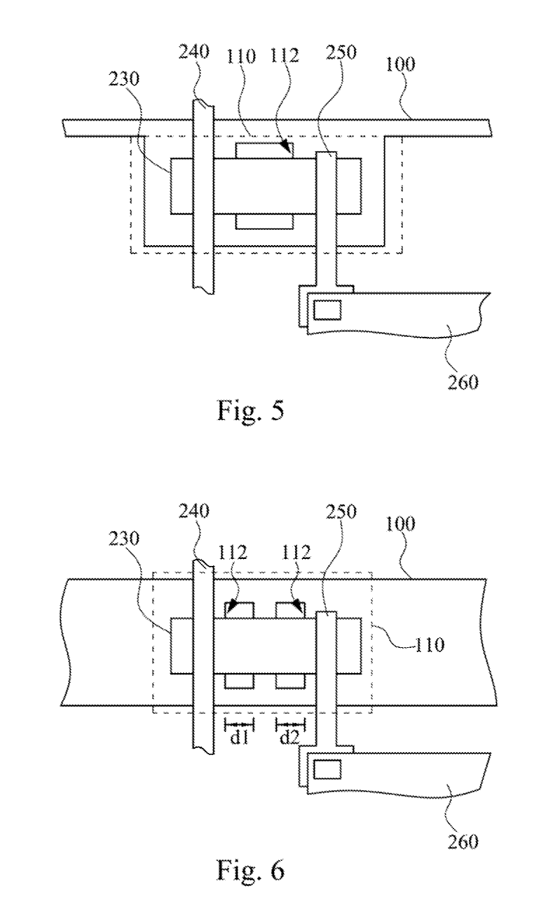

FIG. 5 is a top view of the transistor according to the second embodiment of the present invention. In this embodiment, the transistor is electrically connected to the gate line 100. The gate electrode 110 of the transistor sticks out of the gate line 100. The gate electrode 110 includes at least one closed opening 112. At least one portion of the channel layer 230 overlaps at least one portion of the closed opening 112, and another portion of the channel layer 230 overlaps the gate electrode 110. The source electrode 240 and the drain electrode 250 are separately disposed on the channel layer 230, and the source electrode 240 and the drain electrode 250 are disposed at opposite sides of the closed opening 112. The pixel electrode 260 is electrically connected to the drain electrode 250.

The difference between the transistor of the second embodiment and the transistor of the first embodiment is the relationship between the gate electrode 110 and the gate line 100. In one or more embodiments, there may be no substantially edge between the gate electrode 110 and the gate line 100, as shown in FIG. 2. However, in other embodiments, the gate electrode 110 may be branched from the gate line 100, as shown in FIG. 5. In specifically, the gate electrode 110 may be branched from one side of the gate line 100, or may be branched from both two side of the gate line 100, but the scope of the claimed invention should not be limited in these respects. Therefore, since the gate electrode 110 is only at a transistor forming position of the gate line 100, the layout area of the other portion of the gate line 100 can be reduced, such that the aperture ratio of the pixel structure can be increased. Moreover, a gap between the two sides of the closed opening 112 next to the source electrode 240 and the drain electrode 250 may be between 1.5 μm to 5 μm to restrain or reduce the leakage current, but the scope of the claimed invention should not be limited in this respect.

The materials of the gate electrode 110, the source electrode 240, and the drain electrode 250 includes MoW, Mo, Al, Ti, Ag, Au, or any combination thereof. The material of the channel layer 230 includes amorphous silicon, poly-silicon, amorphous indium gallium zinc oxide (a-IGZO), amorphous indium zinc oxide (a-IZO), gallium nitride, or any combination thereof. The material of the pixel electrode 260 includes indium zinc oxide, indium tin oxide, or any combination thereof. It should be understood that the materials and the forming processes are illustrative only and should not limit the scope of the claimed invention. A person having ordinary skill in the art may choose the materials and the forming processes of each element mentioned above according to actual requirements. As to other relevant materials and process details are all the same as the first embodiment, and, therefore, these are not repeated hereinafter.

FIG. 6 is a top view of the transistor according to the third embodiment of the present invention. In this embodiment, the transistor is electrically connected to the gate line 100. The gate line 100 includes a gate electrode 110, and the gate electrode 110 includes two closed openings 112. At least two portions of the channel layer 230 respectively overlap at least two portions of the closed openings 112. The source electrode 240 and the drain electrode 250 are separately disposed on the channel layer 230, and the source electrode 240 and the drain electrode 250 are disposed at opposite sides of the closed openings 112. The pixel electrode 260 is electrically connected to the drain electrode 250.

The difference between the transistor of the third embodiment and the transistor of the first embodiment is the number of the closed openings 112 disposed between the source electrode 240 and the drain electrode 250 of the transistor. In one or more embodiments, the number of the closed opening 112 is not limited to be one, i.e., there may be plural closed openings 112 on the gate electrode 110 and between the source electrode 240 and the drain electrode 250 of the transistor, and the source electrode 240 and the drain electrode 250 are separately disposed on two opposite sides of the closed openings n112. In specifically, in this embodiment, the closed openings 112 may be two rectangular opening next to each other, and two portions of the channel layer 230 respectively overlap to the two closed opening 112. The two closed openings 112 are disposed between the source electrode 240 and the drain electrode 250, and the two closed openings 112, the source electrode 240, and the drain electrode 250 are arranged along a row. One of the closed openings 112 is next to the source electrode 240, and the other closed opening 112 is next to the drain electrode 250. Therefore, the current flowing between the source electrode 240 and the drain electrode 250 pass the two portions of the channel layer 230 in the two closed openings 112, such that the leakage current of the transistor can be restrained. It should be understood that the number of the closed openings 112 are illustrative only and should not limit the scope of the claimed invention. A person having ordinary skill in the art may design a proper number of the closed openings 112 according to actual requirements.

Moreover, a sum of gaps of each two sides of the closed opening 112 parallel to the source electrode 240 and the drain electrode 250, i.e., gaps d1 and d2 in this embodiment, can be between 1.5 μm to 5 μm, but the scope of the claimed invention should not be limited in this respect.

The materials of the gate electrode 110 the source electrode 240, and the drain electrode 250 includes MoW, Mo, Al, Ti, Ag, Au, or any combination thereof. The material of the channel layer 230 includes amorphous silicon, poly-silicon, amorphous indium gallium zinc oxide (a-IGZO), amorphous indium zinc oxide (a-IZO), gallium nitride, or any combination thereof. The material of the pixel electrode 260 includes indium zinc oxide, indium tin oxide, or any combination thereof. It should be understood that the materials and the forming processes are illustrative only and should not limit the scope of the claimed invention. A person having ordinary skill in the art may choose the materials and the forming processes of each element mentioned above according to actual requirements. As to other relevant materials and process details are all the same as the first embodiment, and, therefore, these are not repeated hereinafter.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A pixel structure, comprising:
a substrate;
a gate line comprising a gate electrode disposed on the substrate, and the gate electrode having at least one closed opening; and
a transistor disposed on the substrate and electrically connected to the gate line, the transistor comprising:
the gate electrode;
a dielectric layer disposed on the gate electrode and the substrate;
a channel layer disposed on a portion of the dielectric layer, and at least one portion of the channel layer overlapping at least one portion of the closed opening;
a source electrode and a drain electrode disposed on the channel layer and at opposite sides of the closed opening; and
a pixel electrode electrically connected to the drain electrode.

2. The pixel structure of claim 1, wherein the gate electrode is a portion of the gate line.

3. The pixel structure of claim 1, wherein the gate electrode is branched from of the gate line.

4. The pixel structure of claim 1, wherein the closed opening is a quadrilateral, and two opposite sides of the closed opening are respectively next to the source electrode and the drain electrode, and the other two sides of the closed opening are not attached to the channel layer.

5. The pixel structure of claim 1, wherein the gate electrode comprises a plurality of the closed opening, and the source electrode and the drain electrode are respectively disposed on the two opposite sides of the closed openings.

6. The pixel structure of claim 5, wherein a sum of gaps of two sides of the closed openings parallel to the source electrode and the drain electrode is 1.5 μm to 5 μm.

7. The pixel structure of claim 1, wherein a gap of two sides of the closed opening next to the source electrode and the drain electrode is 1.5 μm to 5 μm.

8. The pixel structure of claim 1, wherein the transistor further comprises a passivation covering the channel layer, the source electrode, and the drain electrode.

9. The pixel structure of claim 1, wherein the transistor further comprises two doping layers respectively disposed between the channel layer and the source electrode, and between the channel layer and the drain electrode.

10. The pixel structure of claim 1, wherein the structure of the transistor is a back channel etching (BCE) type, a channel project (CHP) type, a coplanar type, or a stagger type.
